(19) United States
(12) Patent Application Publication
(10) Pub. No.: US 2004/0244830 A1
(43) Pub. Date: Dec. 9, 2004

(54) Thermophotovoltaic power generation system

(75) Inventors: Koji Hokoi, Susono-shi (JP); Kiyohito Murata, Susono-shi (JP); Akinori Sato, Susono-shi (JP)

Correspondence Address: Finnegan, Henderson, Farabow,, Garrett & Dunner, L.L.P., 1300 I Street, N.W., Washington, DC, 20005-3315, US

(73) Assignee: Toyota Jidosha Kabushiki Kaisha

(21) Appl. No.: 10/857,918

(22) Filed: Jun. 2, 2004

(30) Foreign Application Priority Data
Jun. 3, 2003 (JP) 2003-158211

(51) Int. Cl. H01L 31/00

(52) U.S. Cl. 136/253

(57) ABSTRACT

A thermophotovoltaic power generation system, improved in power generation system by keeping to a minimum the effect of the temperature profile of the combustion gas and/or effectively utilizing the light emitted from a combustion chamber, converting radiant light from a light emitter heated by a combustion gas to electric power by a photovoltaic converter, provided at a plurality of portions on the path of the combustion gas with light emitters having light emission characteristics suitable for the temperatures of the combustion gas at those portions and photovoltaic converters facing the light emitters at the plurality of portions and having a power generation wavelength ranges corresponding to the wavelengths of the radiant light from the light emitters or provided with a combustion chamber comprised of the same material as the light emitters.

### BACKGROUND OF THE INVENTION

1. Field of the Invention

The present invention relates to a thermophotovoltaic power generation system (TPV system) for converting radiant light from a light emitter heated by combustion gas to electric power by a photovoltaic converter (PV cell).

2. Description of the Related Art

As technology for directly obtaining electrical energy from fossil fuel or flammable gas, attention is being focused on generation of power by thermophotovoltaic energy conversion, that is, thermophotovoltaic power generation (TPV power generation). TPV power generation heats a light emitter (radiator or emitter) by combustion gas ejected from a combustion chamber to generate radiant light from the light emitter and irradiates the light to a photovoltaic converter (PV cell) to obtain electrical energy. A TPV system does not having any moving parts, so can realize a soundless, vibration-free system. TPV power generation is superior in the points of cleanliness, silence, etc. as a next generation source of energy.

FIG. 1 shows a typical example of a thermophotovoltaic power generation system of the related art (see for example Japanese Unexamined Patent Publication (Kokai) No. 2002-315371 and Japanese Unexamined Patent Publication (Kokai) No. 2002-319693). The illustrated thermophotovoltaic power generation system 100 is comprised of a combustion chamber 102 made of stainless steel or another heat resistant metal material around which a light emitter 104 and a photovoltaic converter 106 are wound and a heat resistant housing 110 accommodating the entire assembly.

Fuel F is introduced from the center of the bottom of the system 100 and combustion air A1 from the outer circumference of the bottom. The fuel F rises in a fuel pipe 112 and is burned by the combustion air A1 to generate a flame B. The combustion gas produced by the combustion proceeds as a rising flow G1 and strikes the top 104T of the light emitter 104 where it flows radially toward the outsides and then proceeds through the clearance between the wall of the combustion chamber 102 and the light emitter 104 as the descending flow G2. At this time, the light emitter 104 is heated by the descending flow G2 and generates radiant light of a specific wavelength range. This radiant light reaches the photovoltaic converter 106 where it is converted to electricity.

A filter 108 interposed between the light emitter 104 and the photovoltaic converter 106 is produced from heat resistant glass etc., prevents combustion gas or radiant heat from reaching the photovoltaic converter 106 through the light emitter 104, and passes light of a wavelength suitable for the photovoltaic converter 106.

The descending flow G2 of combustion gas proceeds further downward and transmits heat through a heat exchanger 120 made of stainless steel or another heat resistant metal material to the rising flow of combustion air A1. A heat insulating material 122 is provided between the circumference of the light emitter 104 at this portion and the bottom of the system. The combustion gas proceeds further downward and is discharged outside of the system from an exhaust port 124 at the bottom of the system.

Due to a blower fan 118 provided at the top of the system 100, cooling air A2 is blown into the system. It descends through the space between the photovoltaic converter 106 and the housing 110 while cooling the photovoltaic converter 106 from the outer circumference and descends further and is discharged from an exhaust port 124 at the bottom of the system to the outside of the system.

The thermophotovoltaic power generation system of the above related art has the light emitter 104 formed by a single type of light emitting substance as a whole and further has the photovoltaic converter 106 formed by a single type of element as a whole. This led to the following problems.

The first problem was due to the change in temperature of the light emitter 104 heated by the combustion gas depending on the portion due to the drop in temperature along with the progress in the combustion gas. That is, the combustion gas is highest in temperature at the top part right after being ejected from the combustion chamber 102. As it proceeds as a descending flow G2, it falls in temperature, so the light emitter 104 heated by the descending gas G2 also becomes lower in temperature the lower the portion. In general, a light emitting substance increases in amount of light emission and becomes shorter in wavelength (higher in energy) emitted the higher the temperature, so along with a drop in temperature, the amount of light emission falls and the wavelength of light emission shifts to the longer wavelength side (lower energy side). Accordingly, a light emitter 104 comprised of one type of light emitting substance ends up fluctuating in both the amount of light emission and wavelength of light emission depending on the portion.

The second problem is due to the first problem. That is, the photovoltaic converter 106 has a specific wavelength region suitable for power generation, so if the amount of light emission and wavelength of light emission fluctuate according to the portion of the light emitter 104, the conversion efficiency of the photovoltaic converter 106 for changing the radiant light to electric power ends up fluctuating.

In this way, since the combustion gas inevitably falls in temperature as the combustion gas proceeds along its path, in a thermophotovoltaic power generation system of the related art comprised of a combination of a single type of light emitter 104 and a single type of photovoltaic converter 106, the optimum thermophotovoltaic conditions for the system as a whole cannot be secured and a high power generation efficiency cannot be obtained.

As another problem, the combustion chamber is comprised of stainless steel or another graybody which first absorbs heat energy, emits a large amount of infrared light of a wavelength band invalid for the photovoltaic element, and radiates useless energy not contributing to power generation, therefore cannot obtain a high power generation efficiency.

### SUMMARY OF THE INVENTION

An object of the present invention is to provide a thermophotovoltaic power generation system improved in power generation efficiency by keeping to a minimum the effect of the temperature profile of the combustion gas and/or effectively utilizing the light emitted from the combustion chamber.

To attain the above object, according to a first aspect of the invention, there is provided a thermophotovoltaic power generation system, for converting radiant light from a light emitter heated by combustion gas to electric power by a photovoltaic converter, provided at a plurality of portions on the path of the combustion gas with light emitters having light emission properties suitable for the temperatures of the combustion gas at those portions.

By the basic configuration of providing a plurality of portions on the path of the combustion gas with light emitters having light emission characteristics suitable for the temperatures of the combustion gas at those portions, it is possible to emit radiant light of specific wavelength bands with high light emission efficiencies for the different portions and possible to improve the light emission efficiency of the system as a whole.

Preferably, the system is provided with photovoltaic converters facing the light emitters at the plurality of portions and having power generation wavelength ranges corresponding to the wavelengths of the radiant light from the light emitters. Due to this, in addition to the improvement of the light emission efficiencies of the light emitters due to the above configuration, the combination of the light emitters and the photovoltaic converters is optimized and the power generation efficiency is further enhanced as a system as a whole.

Preferably, the system is provided with light blocking means between portions of provision of the light emitters and/or between portions of provision of the photovoltaic converters. Due to this, radiant lights of different wavelengths are prevented from being mixed between adjoining portions, so it is possible to obtain a high photovoltaic conversion efficiency without unnecessarily raising the temperatures of the photovoltaic converters of the different portions. In particular, by leakage of the radiant light from the high temperature portions, the thermophotonic conversion efficiency at the high temperature region where a high light emission is obtained is enhanced.

Preferably, the system is provided with means for increasing a contact time between the combustion gas of a high temperature right after being ejected from a combustion chamber and the light emitters. The means for increasing the contact time may be a plurality of ejection ports of combustion gas from the combustion chamber or means for changing a direction of combustion gas ejected from the combustion chamber. Due to this, the heat conduction efficiency from the combustion gas at the high temperature portion to the light emitters is raised and the thermophotonic conversion efficiency in the high temperature region where a high light emission is obtained is enhanced.

According to a second aspect of the invention, there is provided a thermophotovoltaic power generation system for converting radiant light from a light emitter heated by combustion gas discharged from a combustion chamber to electric power by a photovoltaic converter, wherein the combustion chamber is comprised of the same material as the light emitter.

In the second aspect of the invention, the combustion chamber is made of the same material as the light emitter. If fabricating the combustion chamber by stainless steel or another heat resistant metal material, the heat energy of the combustion gas heating the combustion chamber is wastefully consumed. By fabricating the combustion chamber by the same material as the light emitter, the combustion chamber itself can function as a light emitter and therefore the thermophotonic conversion efficiency is enhanced.

The first and second aspects of the invention exhibit the effect of improvement of the power generation efficiency. By combining the two aspects of the invention, the effect can be further enhanced.

### BRIEF DESCRIPTION OF THE DRAWINGS

These and other objects and features of the present invention will become clearer from the following description of the preferred embodiments given with reference to the attached drawings, wherein:

FIG. 1 is a cross-sectional view of a thermophotovoltaic power generation system of the related art;

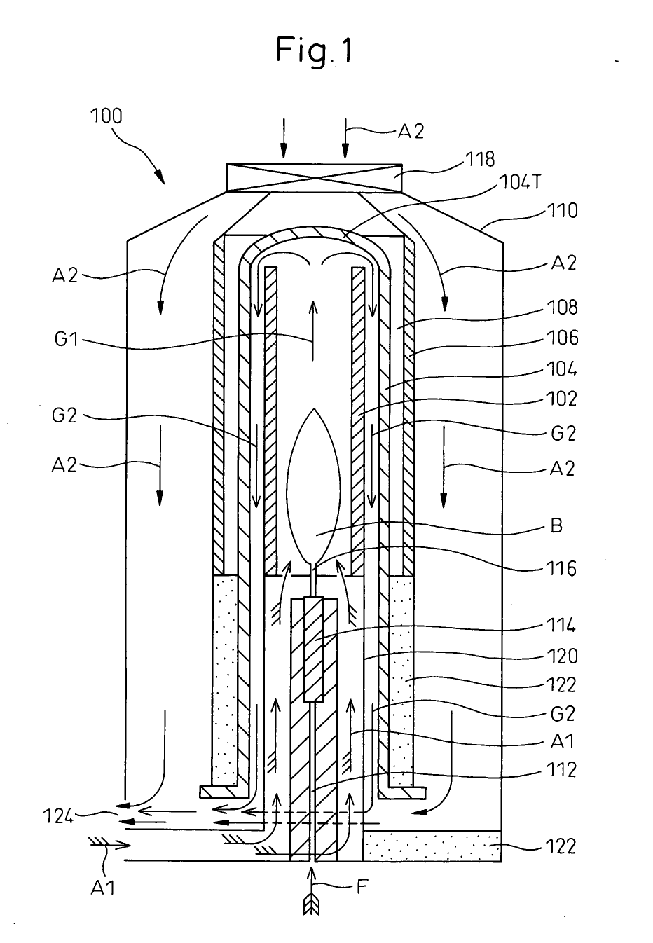

FIG. 2 is a cross-sectional view of a thermophotovoltaic power generation system of a first embodiment according to a first aspect of the present invention;

FIG. 3 is a graph of the relationship between the light emission wavelength bands of individual light emitters and sensitivity regions of photovoltaic converters;

FIG. 4 is a graph of the relationship of light emission wavelength bands and photoelectric converters suitable for combination when changing the temperature of an SiC light emitter;

FIGS. 5A and 5B are views of a thermophotovoltaic power generation system of a second embodiment according to the first aspect of the invention, wherein FIG. 5A is a cross-sectional view and FIG. 5B is a partial plan view;

FIGS. 6A to 6E are views of a thermophotovoltaic power generation system of a third embodiment according to the first aspect of the invention, wherein FIG. 6A is a cross-sectional view, FIG. 6B is a partial plan view, FIG. 6C is a partial plan view, FIG. 6D is a partial cross-sectional view, and FIG. 6E is a partial cross-sectional view;

FIG. 7 is a partial cross-sectional view of a thermophotovoltaic power generation system of a fourth embodiment according to the first aspect of the invention;

FIG. 8 is a partial cross-sectional view of a thermophotovoltaic power generation system of a fifth embodiment according to the first aspect of the invention;

FIG. 9 is a partial cross-sectional view of a thermophotovoltaic power generation system of a sixth embodiment according to the first aspect of the invention;

FIG. 10 is a cross-sectional view of a thermophotovoltaic power generation system of a seventh embodiment according to a second aspect of the invention;

FIG. 11 is a cross-sectional view of a thermophotovoltaic power generation system of an eighth embodiment according to the second aspect of the invention; and

FIG. 12 is a cross-sectional view of a thermophotovoltaic power generation system of a ninth embodiment according to the second aspect of the invention.

### DESCRIPTION OF THE PREFERRED EMBODIMENTS

Preferred embodiments of the present invention will be described in detail below while referring to the attached figures.

First Embodiment

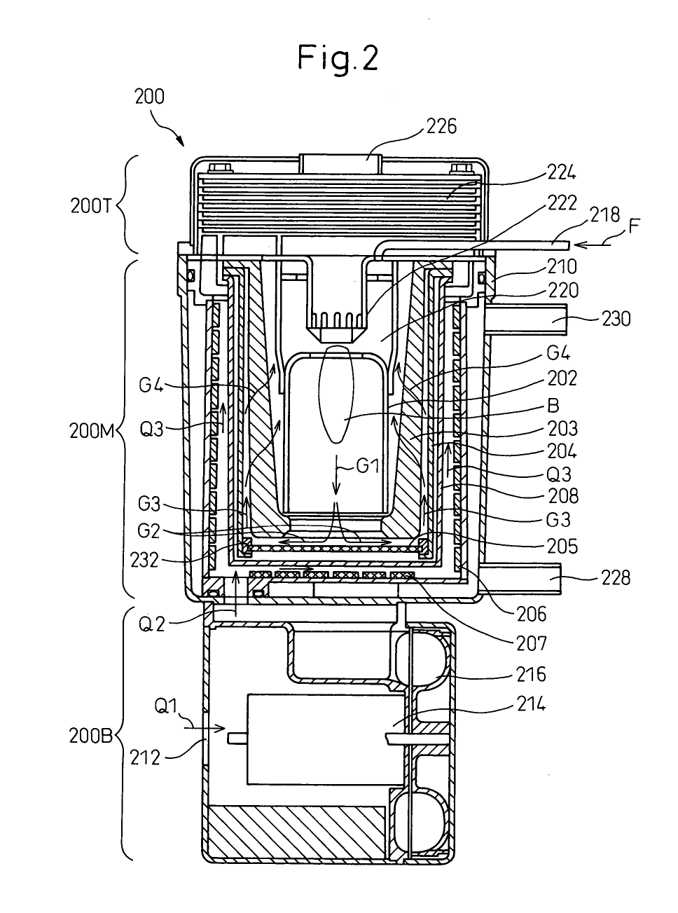

FIG. 2 shows an example of a thermophotovoltaic power generation system according to a preferred embodiment of the first aspect of the invention. The illustrated thermophotovoltaic power generation system 200 is comprised of a heat exchanger 200%, a center main unit 200M, and a bottom air feeder 200B.

The main unit 200M is comprised of a combustion chamber 202 made of stainless steel or another heat resistant metal material around which light emitters 203, 204, and 205 and photovoltaic converters 206 and 207 are wound and a heat resistant housing 210 accommodating the entire assembly. A filter 208 made of heat resistant glass etc. is interposed between the light emitters 204 and 205 and the photovoltaic converters 206 and 207. This prevents the combustion gas and radiant heat from reaching the photovoltaic converters 206 and 207 through the light emitters 204 and 205 and passes light of wavelengths suitable for the photovoltaic converters 206 and 207.

The air feeder 200B takes in outside air from an introduction port 212 (arrow Q1) and supplies it to the main unit 200M as an air flow (arrow Q2) by a blower 216 driven by a motor 214. The air flow supplied to the main unit passes between the filter 208 and the photovoltaic converters 206 and 207 and rises (arrow Q3) while cooling the photovoltaic converters 206 and 207, then enters a premixing chamber 220 through the higher heat exchanger 224.

On the other hand, fuel F is introduced from a fuel introduction port 218 at the top of the main unit 200M and enters the premixing chamber 220 where it is mixed with the above air. The mixed gas formed is burned by a burner 222 at the top of the combustion chamber 202 and produces a downward flame B. The combustion gas produced due to the combustion is ejected from the combustion chamber 202 as a downward flow G1, strikes the light emitter 205 at the bottom, flows outward radially (arrow G2), and flows rising between the wall of the light emitter 203 surrounding the combustion chamber 202 immediately at its outside and the light emitter 204 surrounding the outside of that (arrow G3). At this time, the light emitter 205 is heated by the radiant flow G2 of the combustion gas, the light emitter 204 is heated by the rising flow G3 of the combustion gas, and radiant lights of wavelength ranges unique to the light emitters are emitted. The inside light emitter 203 is formed as a porous member and is heated by combustion gas flowing through the inside (arrow G4). The radiant lights from the light emitters 203 and 204 pass through the filter 208 to reach the facing photovoltaic converter 206, while the radiant light from the light emitter 205 passes through the filter 208 to reach the facing photovoltaic converter 207, where they are converted to electric power.

The rising flows G3 and G4 of the combustion gas proceed further upward, heat the air at a heat exchanger 224 comprised of stainless steel or another heat resistant metal material, then are discharged from an exhaust port 226 to the outside of the system.

Further, an introduction port 228 and exhaust port 230 are provided for cooling water for cooling photovoltaic converters 206 and 207 from the back.

Here, the characterizing feature of the preferred embodiment of the first aspect of the invention is the selection and combination of the light emitters 203, 204, and 205 at the different portions and the photovoltaic converters 206 and 207. First, the portion which the combustion gas (G2) ejected from the combustion chamber 202 first strikes becomes the highest temperature, so the light emitter 205 at that portion is made Yb₂O₃ with a high thermophotonic conversion efficiency at a high temperature and the photovoltaic converter 207 at the portion facing it is made Si with a high photovoltaic conversion efficiency with respect to the radiant light of the short wavelength radiated from the Yb₂O₃ light emitter 205 at a high temperature. As opposed to this, the portion along with rising flow (G3) of the combustion gas falls in temperature of the combustion gas, so the light emitters 203, 204 at this portion are made Er₂O₃ with a high thermophotonic conversion efficiency at a low temperature, while the photovoltaic converters 206 facing these are made Ge with a high photovoltaic conversion efficiency with respect to the radiant light of the long wavelength radiated from the Er₂O₃ at a low temperature.

That is, the portion where the combustion gas is high in temperature is made a combination of a Yb₂O₃ light emitter 205/Si photovoltaic converter 207, while the portion where the combustion temperature falls is made a combination of Er₂O₃ light emitters 203 and 204/Ge photovoltaic converter 206.

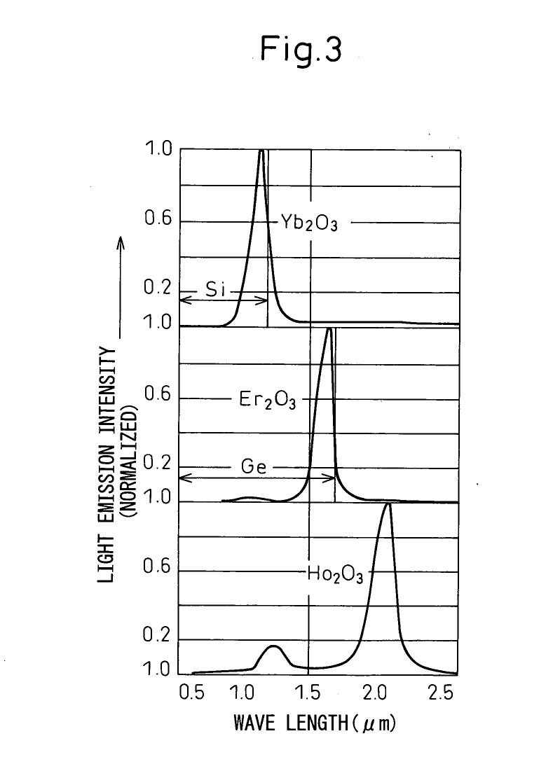

In this way, in the first aspect of the invention, a selective light emitter for converting the majority of the input energy to light of the sensitivity region of the photovoltaic converter is used. As a light emitter emitting light by a wavelength convenient for thermophotovoltaic power generation generation, a light emitter using a rare earth element is used. The rare earth element, as shown in FIG. 3, includes Yb with a light emission band center wavelength of 1.0 μm, Er with one of 1.5 μm, Ho of one of 2.0 μm, etc. A light emitter suitable for the temperature region used and the sensitivity region of the photovoltaic converter is used.

As the combination of photovoltaic converters and light emitters, as shown in FIG. 3, Yb₂O₃, which has a strong light emission in the sensitivity wavelength region of Si as the photovoltaic converter, is combined as the light emitter. When using GaSb or Ge as the photovoltaic converter, Er₂O₃ which has a strong light emission in these sensitivity wavelength regions is combined as the light emitter. The power generation efficiencies of these combinations are a maximum of 45% for Er/Ge and a maximum of 60% for Yb/Si. Using Si gives a higher power generation efficiency. However, in the case of Si, the energy for forming the electron/hole pairs corresponds to light of a wavelength of 1 μm. The shorter the wavelength of light, the larger the energy held, so with an Si photovoltaic converter, electric power cannot be obtained unless struck by light of a wavelength shorter than 1 μm. Therefore, in the past, use of Si as a photovoltaic converter in a thermophotovoltaic power generation system using a selective light emitter was avoided due to the narrowness of the sensitivity region.

In the first aspect of the invention, by combining the photovoltaic converters and light emitters to correspond to the temperature profile of the combustion gas, it is possible to concentratedly use Si having a narrow sensitivity region, but a high photovoltaic conversion efficiency in the short wavelength band in the high temperature region of the combustion gas, so it is possible to greatly improve the power generation efficiency of the thermophotovoltaic power generation system as a whole compared with the related art.

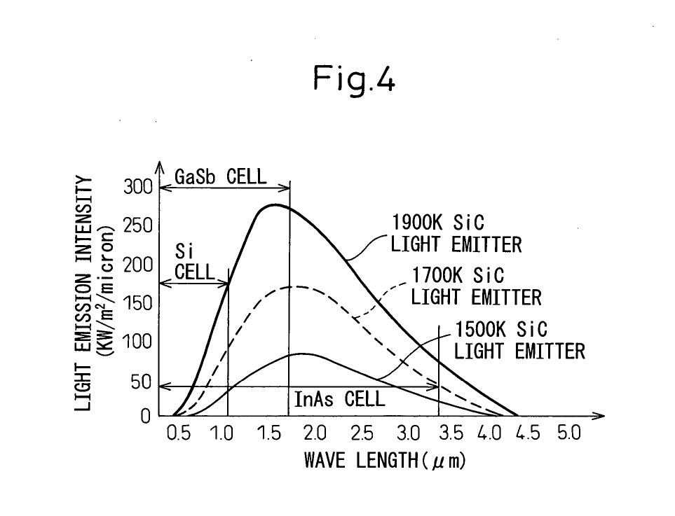

FIG. 4 shows the light emission wavelength bands at various light emitter temperatures for the case of using SiC as a light emitter. A light emitter increases in the amount of light emission and becomes larger in the light emission intensity as the light emission band as a whole the higher the temperature and simultaneously the intensity of the short wavelength component in the light emission band becomes relatively larger than the long wavelength component. As a result, the higher the light emitter in temperature, the greater the intensity of the wavelength component in the sensitivity region of Si with a good light emission efficiency as explained above. Therefore, by making positive use of an Si photovoltaic converter at a high temperature portion heated by the combustion gas right after ejection and using an optimal combination of photovoltaic converters/light emitters for the following relatively low temperature portions as well, high efficiency power generation is realized.

Table 1 shows typical examples of combinations of photovoltaic converters/light emitters corresponding to different light emitter temperatures.

TABLE 1

| | Light | Selected | | Power |
|---|---|---|---|---|
| | emitter | radiant | Photovoltaic | generation |
| Light | temperature | center | converter | efficiency |
| emitter | (K) | wavelength (μm) | (bandgap: eV) | (%) |
| Yb₂O₃ | 2000 | 1.0 | Si (1.12) | 60 |
| Er₂O₃ | 1500 | 1.5 | GaSb (0.72), | 45 |
| | | | Ge (0.66) | |

Note that in the preferred embodiment shown in FIG. 2, a diaphragm 232 is provided at the boundary of the high temperature portion of the combination of the Yb₂O₃ light emitter 205/Si photovoltaic converter 207 and the low temperature portion of the combination of the Er₂O₃ light emitters 203 and 204/Ge photovoltaic converter 206. Due to this, the intermixture of radiant light of different wavelength bands (in particular from the high temperature side to the low temperature side) is reduced and the conversion efficiencies at the high temperature portion and low temperature portion are further enhanced,

The important point to note in the present embodiment is the effective utilization of the high temperature region, that is, how efficiently the Si photovoltaic converter suitable for the high temperature region can be made to operate. For this, it is necessary to efficiently raise the temperature of the Yb₂O₃ light emitter. Below, embodiments according this preferred aspect will be explained.

Second Embodiment

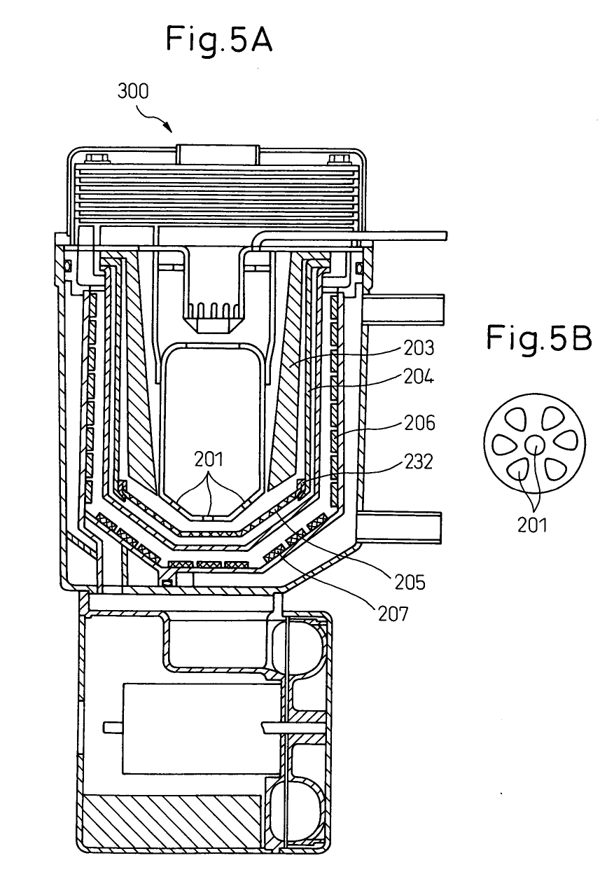

FIGS. 5A and 5B show an example of a thermophotovoltaic power generation system according to a further preferred embodiment of the first aspect of the invention. FIG. 5A is a cross-sectional view showing the system as a whole, while FIG. 5B is a plan view showing only the part of the ejection port. The illustrated thermophotovoltaic power generation system 300 is the same as the first embodiment in basic structure (FIG. 2), but is characterized in the structure of the high temperature portion.

That is, the combustion gas is ejected from a plurality of small ejection ports 201 to raise the gas flow rate. Further, the surface perpendicular to the flow of ejection gas is made larger, the Yb₂O₃ light emitter 205 is arranged at that surface, and the contact time between the high temperature gas 205 and the Yb₂O₃ light emitter is increased so as to raise the heat conduction efficiency from the combustion gas to the light emitter. The Si photovoltaic converter 207 combined with the Yb₂O₃ light emitter 205 is also arranged at a plane parallel to the plane of provision of the Yb₂O₃ light emitter 205.

Note that in this embodiment as well, a diaphragm 232 is provided at the boundary of the high temperature portion and the low temperature portion to restrict intermixture of light between two portions (in particular from the high temperature side to the low temperature side).

Third Embodiment

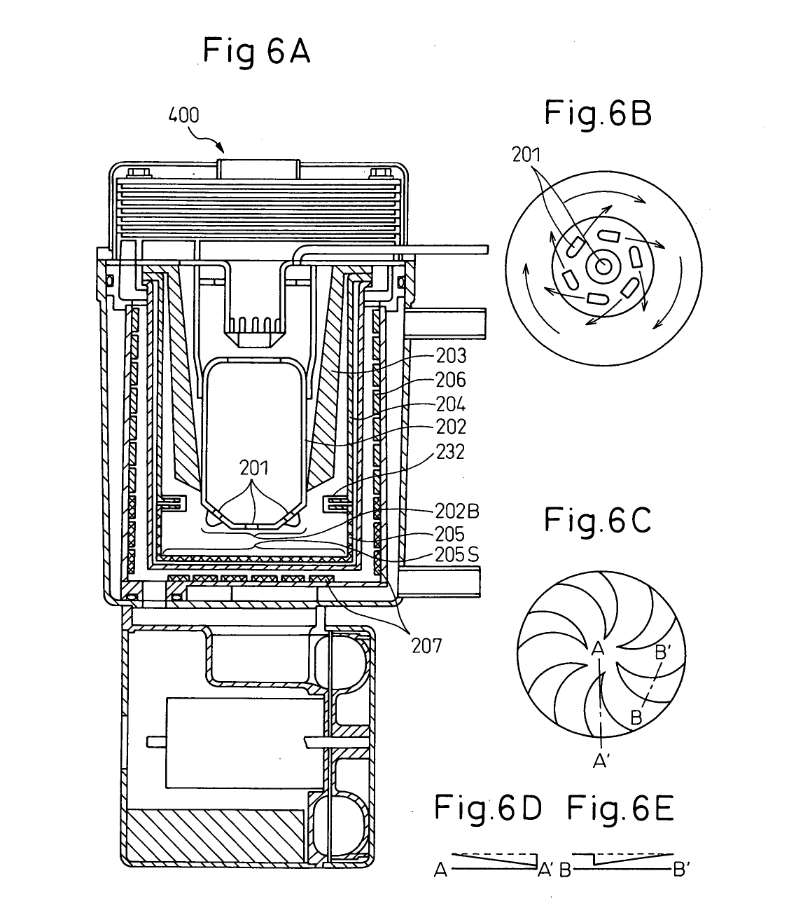

FIGS. 6A to 6E show an example of a thermophotovoltaic power generation system according to another preferred embodiment of the first aspect of the invention. FIG. 6A, shows a cross-sectional view of the system as a whole, FIG. 6B is a plan view of a bottom 202B of the combustion chamber 202, FIG. 6C is a plan view of the surfaces 205S of a group of Yb₂O₃ light emitters 205 arranged at the bottom, and FIG. 6D and FIG. 6E are cross-sectional views along the line A-A′ and the line B-B′ of FIG. 6C.

The thermophotovoltaic power generation system 400 illustrated is the same as the first embodiment (FIG. 2) in basic structure, but is characterized in the high temperature portion.

That is, the combustion gas is ejected from the plurality of small ejection ports 201 to raise the gas flow rate. Further, as shown in FIG. 6B, by making the ejection port 201 a pipe in form, the combustion gas is ejected as a swirl in flow. Corresponding to this, the surfaces 205S of the group of Yb₂O₃ light emitters 205 arranged at the bottom are shaped in a swirl as shown in FIG. 6C to promote the swirl flow of the combustion gas. The individual swirl flow surfaces are inclined in the radial direction and circumferential direction as shown in FIG. 6D and FIG. 6E. Due to this, the contact time between the high temperature gas 205 and Yb₂O₃ light emitters is increased to raise the heat conduction efficiency of the light emitters from the combustion gas.

Note that in this embodiment as well, a diaphragm 232 is provided at the boundary of the high temperature portion of the combination of the Yb₂O₃ light emitters 205/Si photovoltaic converter 207 and the low temperature portion of the combination of the Er₂O₃ light emitters 203, 204/Ge photovoltaic converter 206 to restrict the intermixture of light between the two portions (in particular from the high temperature side to the low temperature side).

Fourth Embodiment

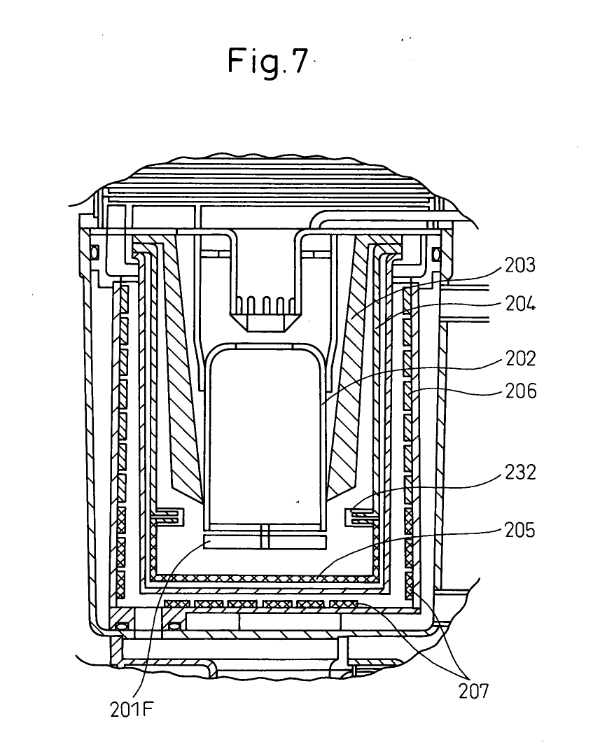

FIG. 7 shows an example of a thermophotovoltaic power generation system according to another preferred embodiment of the first aspect of the invention by a partial cross-sectional view. In this embodiment, fins 201F are provided in front of the ejection ports. Due to this, in the same way as the third embodiment, the contact time of the high temperature gas 205 and the Yb₂O₃ light emitter is increased to enhance the heat conduction efficiency from the combustion gas to the light emitters.

Note that in this embodiment as well, a diaphragm 232 is provided at the boundary of the high temperature portion of the combination of the Yb₂O₃ light emitter 205/Si photovoltaic converter 207 and the low temperature portion of the combination of the Er₂O₃ light emitter 203, 204/Ge photovoltaic converter 206 to restrict the intermixture of light between the two portions (in particular from the high temperature side to the low temperature side).

Fifth Embodiment

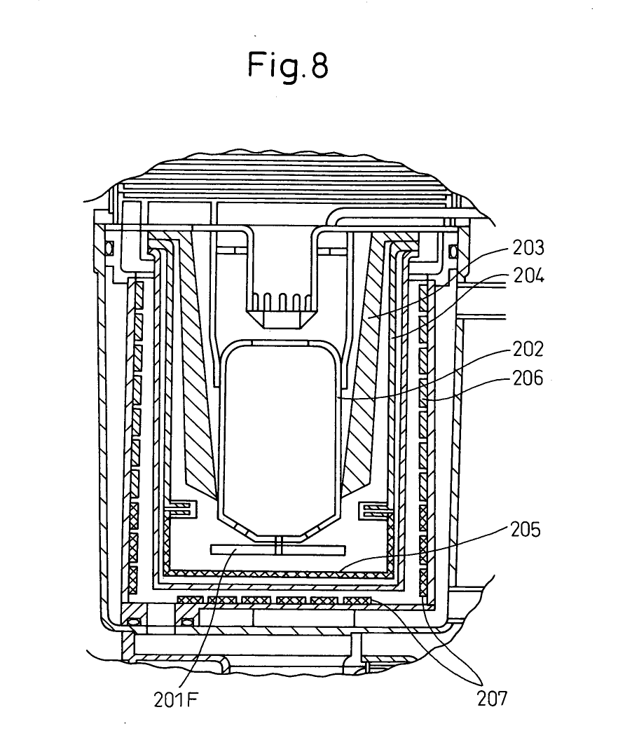

FIG. 8 shows an example of a thermophotovoltaic power generation system according to another preferred embodiment of the first aspect of the invention. In the present embodiment, a “pipe shaped ejection port+bottom light emitter surface shape” according to the third embodiment (FIG. 6) and “fins in front of ejection port” according to the fourth embodiment (FIG. 7) are combined. Due to this, the formation of a swirl flow is further promoted, so the effect of improvement of the heat conduction efficiency due to an increase in the combustion gas/light emitter contact time is further enhanced.

Note that in this embodiment as well, a diaphragm 232 is provided at the boundary of the high temperature portion of the combination of the Yb₂O₃ light emitter 205/Si photovoltaic converter 207 and the low temperature portion of the combination of the Er₂O₃ light emitters 203 and 204/Ge photovoltaic converter 206 to restrict the intermixture of light between the two portions (in particular from the high temperature side to the low temperature side).

Sixth Embodiment

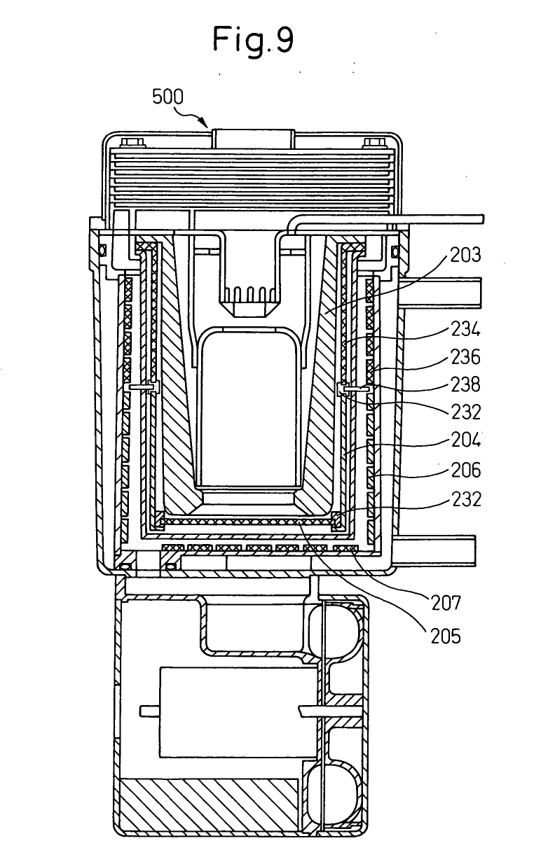

FIG. 9 shows an example of a thermophotovoltaic power generation system of another preferred embodiment of the first aspect of the invention. The illustrated thermophotovoltaic power generation system 500 is the same as the first embodiment (FIG. 2) in the basic structure, but is characterized by the structure of the combination of the light emitters/photovoltaic converters in the high temperature, medium temperature, and low temperature. That is, the high temperature portion is made a combination of a Yb₂O₃ light emitter 205/Si photovoltaic converter 207, the medium temperature portion is made a combination of an Er₂O₃ light emitter 204/Ge photovoltaic converter 206, and the low temperature portion is made a combination of the SiC light emitter 234/InAs photovoltaic converter 236. Due to this, it is possible to obtain a more suitable correspondence between the temperature regions of the combustion gas and the light emitters/photovoltaic converters and possible to effectively utilize even the combustion gas energy of the low temperature region and therefore the power generation efficiency is further enhanced.

Note that in this embodiment as well, diaphragms 232 are provided at the boundaries of the high temperature portion (Yb₂O₃ light emitter 205/Si photovoltaic converter 207), medium temperature portion (Er₂O₃ light emitter 204/Ge photovoltaic converter 206), and low temperature portion (SiC light emitter 234/InAs photovoltaic converter 236) to restrict the intermixture of the light between adjoining portions (in particular, from the high temperature side to the low temperature side). Further, a reflection plate is arranged at the boundary of the medium temperature portion (Er₂O₃ light emitter 204/Ge photovoltaic converter 206) and low temperature portion (SiC light emitter 234/InAs photovoltaic converter 236) to further restrict the intermixture of the light between the two portions (in particular from the high temperature to the low temperature side).

Seventh Embodiment

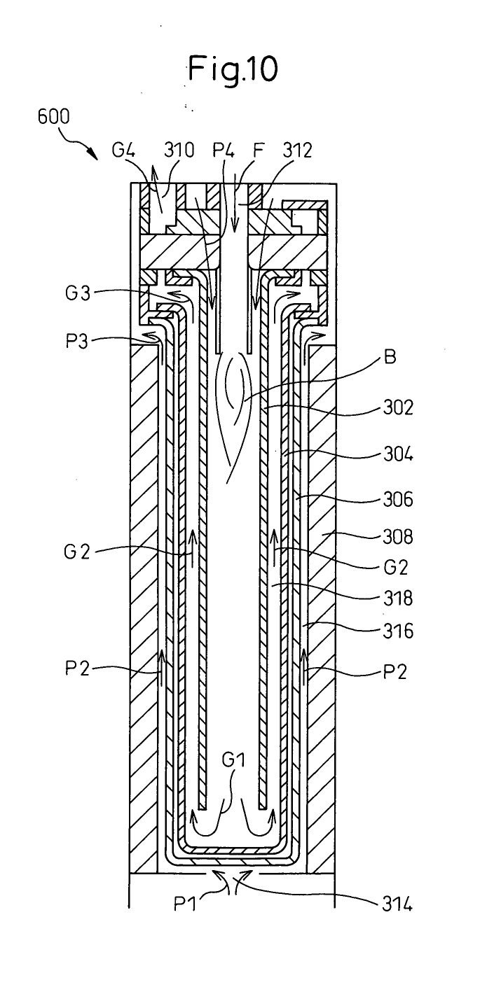

FIG. 10 shows an example of a thermophotovoltaic power generation system according to a preferred embodiment of a second aspect of the invention. The illustrated system 600 is substantially cylindrical as a whole. The combustion chamber 302 is fabricated of the same material as the light emitter 304. A photovoltaic converter 308 is arranged at the outside of the light emitter 304 via a heat resistant glass filter 306.

The combustion gas F is introduced from a fuel introduction port 312 at the top end of the system and fed downward to the inside of the combustion chamber space 302. The air is introduced from an air introduction port 314 at the top end of the system (arrow P1), rises through the clearance between the filter 306 and photovoltaic converter 308 (arrow P2), then further rises (arrow P3) and is supplied downward from the top end of the system to the inside of the combustion chamber 303 (arrow P4). In the combustion chamber 302, the combustion gas F is burned and a flame B is formed. The combustion gas produced due to this is ejected from the bottom end of the combustion chamber 302, strikes the bottom light emitter 304, proceeds outward in a radial fashion (arrow G1), then rises between the outer circumference of the combustion chamber 302 and the light emitter 304 wound around it (arrow G2). At this time, the combustion chamber 302 and the light emitter 304 comprised of the same material are heated by the combustion gas, radiant light having the same wavelength band is emitted, and the radiant light passes through the filter 306 to reach the photovoltaic converter 308.

The photovoltaic converter 308 having a sensitivity region in the light emission wavelength band of the light emitter 304 effectively absorbs not only the radiant energy from the light emitter 304, but also the radiant energy from the combustion chamber 302 and converts it to electric power, so the power generation efficiency is improved compared with a structure forming the combustion chamber by stainless steel or another graybody.

The used combustion gas further rises (arrow G3) and is discharged from an exhaust port 310 of the top end of the system to the outside of the system.

Eighth Embodiment

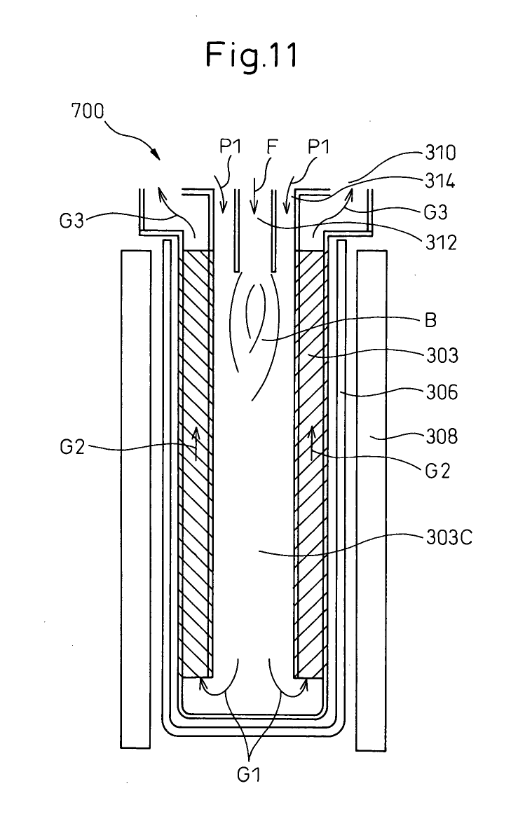

FIG. 11 shows an example of a thermophotovoltaic power generation system according to a preferable embodiment of a second aspect of the invention. The illustrated system 700 is substantially cylindrical as a whole and is provided with a combustion chamber/light emitter 303 fabricated from a porous light emitting material. A photovoltaic converter 308 is arranged at the outside of the combustion chamber/light emitter 303 through a heat resistant filter 306.

The combustion gas F is introduced from a fuel introduction port 312 at the top end of the system and fed downward to the inside of the combustion chamber space 303C. On the other hand, the air is introduced from an air introduction port 314 at the top end of the system and supplied downward to the combustion chamber space 303C where the combustion gas F is burned and a flame B is formed. The combustion gas produced due to this is ejected from the bottom end of the combustion chamber space 303C, strikes the bottom, proceeds outward radially (arrow G1), then rises in the porous combustion chamber/light emitter 303 (arrow G2). At this time, the radiant light produced from the combustion chamber/light emitter 303 made of a light emitting material passes through the filter 306 and reaches the photovoltaic converter 308.

Due to this, the amount of emission of radiant light having a wavelength band suitable for the photovoltaic converter 308 is increased and the power generation efficiency is improved compared with a structure forming the combustion chamber by stainless steel or another graybody.

Ninth Embodiment

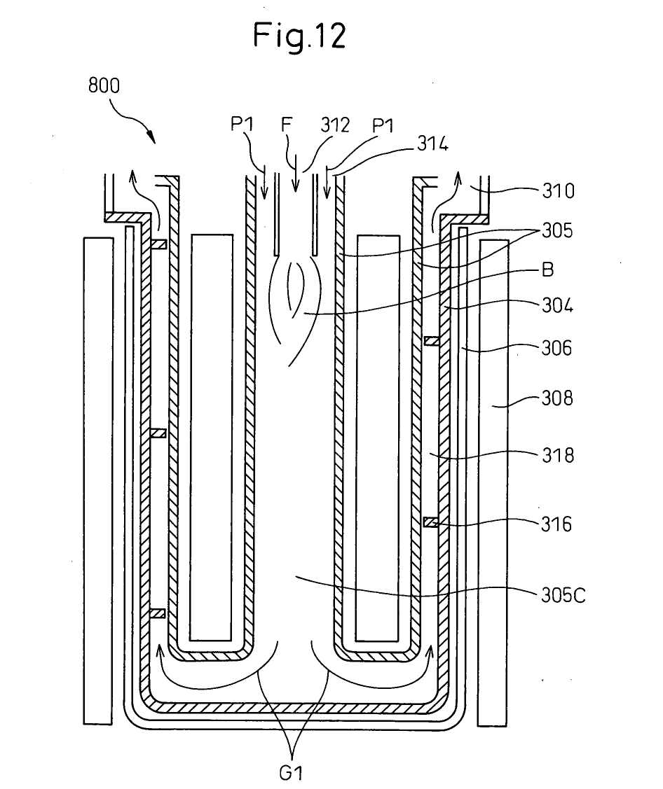

FIG. 12 shows an example of a thermophotovoltaic power generation system according to a preferred embodiment of the second aspect of the invention. The illustrated system 800 is substantially cylindrical as a whole and is comprised of a double wall pipe 305 made of a light emitter material forming the combustion chamber and inside light emitter, a light emitter 304 made of the same light emitter material wound around its outside, and a heat resistant glass filter 306 and photovoltaic converter 308 successively wound around the outside. Spiral fins 316 made of the same light emitter material are formed between the inside light emitter 305 and outside light emitter 304.

In the same way as the eighth embodiment, combustion gas F and air P1 are introduced from introduction ports 312 and 314 at the top end of the system and supplied downward to the combustion chamber space 305C where a flame B is formed by the combustion. The combustion gas produced due to this is ejected from the bottom end of the combustion chamber space, strikes the emitter 304 at the bottom, proceeds outward radially, then rises while swirling with a higher flow rate in the space 318 defined by the spiral fins 316 in the porous combustion chamber/light emitter 303 (arrow G2). Due to this, the combustion gas increases in flow rate, the contact time with the light emitters 304 and 305 increases, and a higher power generation efficiency is obtained compared with the seventh and eighth embodiments.

While the invention has been described with reference to specific embodiments chosen for purpose of illustration, it should be apparent that numerous modifications could be made thereto by those skilled in the art without departing from the basic concept and scope of the invention.

What is claimed is:

1. A thermophotovoltaic power generation system for converting radiant light from a light emitter heated by a combustion gas to electric power by a photovoltaic converter, wherein
said system is provided at a plurality of portions on the path of the combustion gas with light emitters having light emission characteristics suitable for the temperatures of the combustion gas at those portions.

2. A thermophotovoltaic power generation system as set forth in claim 1, wherein said system is provided with photovoltaic converters facing the light emitters at the plurality of portions and having a power generation wavelength ranges corresponding to the wavelengths of the radiant light from the light emitters.

3. A thermophotovoltaic power generation system as set forth in claim 1, wherein said system is provided with light blocking means between portions of provision of the light emitters and/or between portions of provision of said photovoltaic converters.

4. A thermophotovoltaic power generation system as set forth in claim 2, wherein said system is provided with light blocking means between portions of provision of the light emitters and/or between portions of provision of said photovoltaic converters.

5. A thermophotovoltaic power generation system as set forth in any one of claims 1 to 4, wherein said system is provided with means for increasing a contact time between said combustion gas of a high temperature right after being ejected from a combustion chamber and said light emitters.

6. A thermophotovoltaic power generation system as set forth in claim 5, wherein said means for increasing the contact time is comprised of a plurality of ejection ports of combustion gas from said combustion chamber.

7. A thermophotovoltaic power generation system as set forth in claim 5, wherein said means for increasing the contact time is comprised of means for changing a direction of combustion gas ejected from said combustion chamber.

8. A thermophotovoltaic power generation system for converting radiant light from a light emitter heated by combustion gas discharged from a combustion chamber to electric power by a photovoltaic converter, wherein the combustion chamber is comprised of the same material as the light emitter.

9. A thermophotovoltaic power generation system as set forth in any one of claims 1 to 4, wherein said combustion gas is discharged downward from a combustion chamber, strikes the bottommost portion of the light emitters, then rises along the light emitters.

10. A thermophotovoltaic power generation system as set forth in claim 5, wherein said combustion gas is discharged downward from a combustion chamber, strikes the bottommost portion of the light emitters, then rises along the light emitters.

11. A thermophotovoltaic power generation system as set forth in claim 6, wherein said combustion gas is discharged downward from a combustion chamber, strikes the bottommost portion of the light emitters, then rises along the light emitters.

12. A thermophotovoltaic power generation system as set forth in claim 7, wherein said combustion gas is discharged downward from a combustion chamber, strikes the bottommost portion of the light emitters, then rises along the light emitters.

13. A thermophotovoltaic power generation system as set forth in claim 8, wherein said combustion gas is discharged downward from the combustion chamber, strikes the bottommost portion of the light emitters, then rises along the light emitters.
